(19) United States
(12) Patent Application Publication
(10) Pub. No.: US 2009/0052134 A1
(43) Pub. Date: Feb. 26, 2009

(54) LIQUID-COOLED GROUNDED HEATSINK FOR DIODE RECTIFIER SYSTEM

(76) Inventors: Jordan B. Casteel, Roanoke, VA (US); Pedro Monclova, Salem, VA (US); John E. Bittner, Troutville, VA (US); Brian E. Lindholm, Salem, VA (US); Melissa Freeman, Salem, VA (US)

Correspondence Address: NIXON & VANDERHYE P.C., 901 NORTH GLEBE ROAD, 11TH FLOOR, ARLINGTON, VA, 22203, US

(21) Appl. No.: 11/946,108

(22) Filed: Nov. 28, 2007

Related U.S. Application Data
(60) Provisional application No. 60/957,251, filed on Aug. 22, 2007.

(51) Int. Cl. H05K 7/20; H02K 11/04

(52) U.S. Cl. 361/699; 363/141; 310/68 D

(57) ABSTRACT

A diode rectifier system for generator excitation includes a plurality of diode modules mounted on a heatsink and a coolant tube provided in the heatsink. The heatsink is electrically grounded. A method of cooling a diode rectifier system for generator excitation comprises providing a flow of liquid coolant in the coolant tube and electrically grounding the heatsink.

### CROSS REFERENCE TO RELATED APPLICATION

This application claims priority to U.S. Application 60/957,251, filed Aug. 22, 2007, the entire content of which is incorporated herein by reference.

### BACKGROUND OF THE INVENTION

The present invention relates to a liquid-cooled grounded heatsink diode rectifier system for generator excitation applications.

A diode rectifier system may be used to convert alternating current (AC) to direct current (DC). In order to function properly, the heat generated by the diode rectifier system must be removed, for example to a heatsink. Current rectifier systems for generator excitation applications are known which include a plurality of coolant hoses, for example 20 or more, and a plurality of liquid-cooled heatsinks, for example, either 4 or 16. Numerous pieces of soldered copper pipe, all of which may potentially form leaks at the connection points, are used to supply the liquid coolant. Coolant, for example water, is circulated through the heatsinks that are operated at elevated voltages. The elevated voltages require that the current rectifier systems use deionized water, which is more corrosive than regular water and requires a special deionizing system to maintain the non-conductive nature of the water. Moreover, the presence of elevated voltages on wetted surfaces drives ions from the wetted surface into the water, which increases the rate of corrosion. The current rectifiers thus require refurbishing, wherein the eroded or corroded parts are replaced with new parts. However, the refurbishing merely restores the rectifier to the previous condition and all of the weaknesses of the design are maintained, e.g., the opportunities for leaks and the erosion-corrosion effect. After operating for a period of time, the rectifier system will again develop leaks.

It has also been proposed to use air-cooled heatsinks instead of liquid-cooled heatsinks. The air-cooled heatsinks eliminate the leakage problem, but require numerous bulky heatsinks, high-pressure diode clamps, and an extensive electrical isolation infrastructure. The resulting diode rectifier system is thus bulkier and more expensive than a liquid-cooled diode rectifier system.

### BRIEF DESCRIPTION OF THE INVENTION

According to an embodiment of the invention, a diode rectifier system for generator excitation comprises a plurality of diode modules mounted on a heatsink; and a coolant tube provided in the heatsink. The heatsink is electrically grounded.

According to another embodiment of the invention, a method of cooling a diode rectifier system for generator excitation is provided. The diode rectifier system comprises a plurality of diode modules mounted on a heatsink; and a coolant tube provided in the heatsink. The heatsink is electrically grounded. The method comprises providing a flow of liquid coolant in the coolant tube; and electrically grounding the heatsink.

### BRIEF DESCRIPTION OF THE DRAWINGS

FIG. 1 is a perspective view of a liquid-cooled diode rectifier system for generator excitation according to an embodiment of the invention;

FIG. 2 is a perspective view of an isolated diode module usable in the diode rectifier system of FIG. 1; and

FIG. 3 is a perspective view of the liquid-cooled diode rectifier system for generator excitation according to an embodiment of the invention.

### DETAILED DESCRIPTION OF THE INVENTION

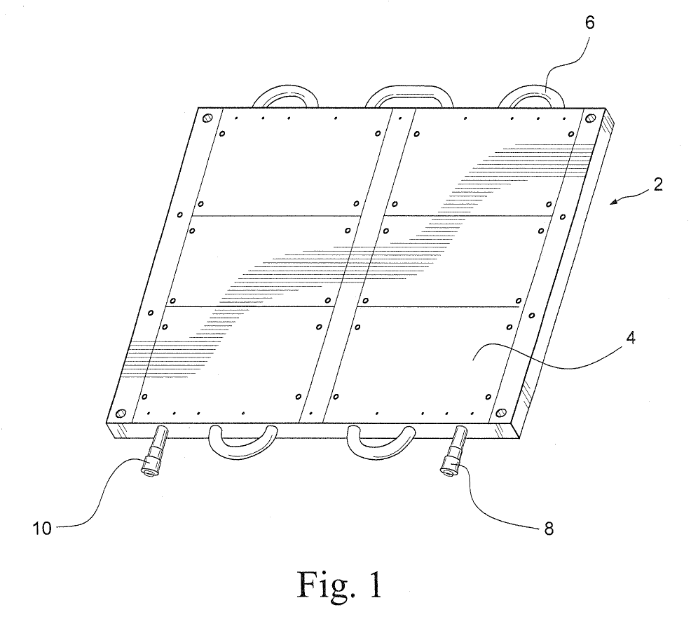

Referring to FIG. 1, a liquid-cooled grounded heatsink diode rectifier system 2 for generator excitation includes a heatsink 4 and a coolant tube 6 configured to carry liquid coolant throughout the heatsink 4. The coolant tube 6 includes a coolant inlet 8 and a coolant outlet 10.

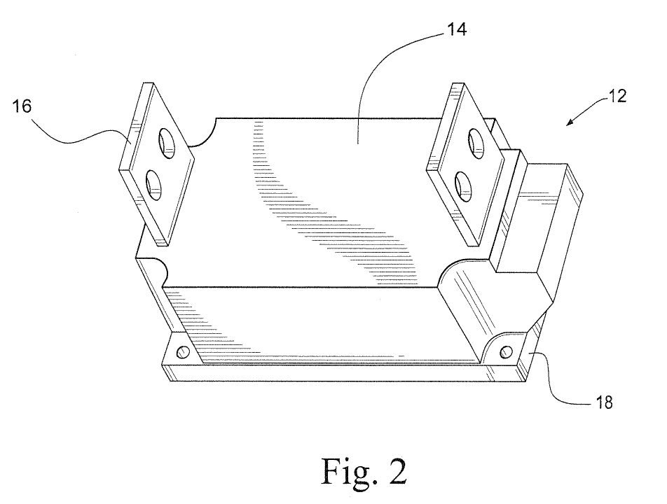

The coolant tube 6 may be a single pre-formed stainless steel tube that is embedded into the heatsink 4. It should be appreciated, however, that other materials may be used for the coolant tube 6 and the heatsink 4. The heatsink 4 is configured to be large enough to hold, at least, six diode modules (FIG. 2) while only having the two coolant connections, the coolant inlet 8 and the coolant outlet 10.

Referring to FIG. 2, a diode module 12 includes a diode 14 and a diode clamp 16. The diode module 12 also includes an insulating layer 18. The internal insulating layer 18 of the diode module 12 may be made of, for example, alumina or aluminum nitride. The internal insulating layer 18 keeps the diode 14 separated from the heatsink 4.

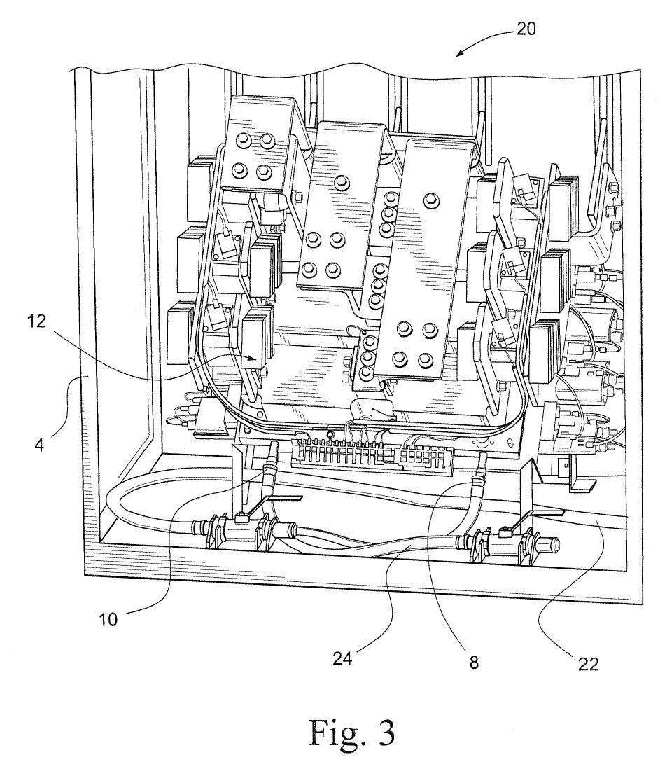

Referring to FIG. 3, the liquid-cooled grounded heatsink diode rectifier system 2 includes six diode modules 12 mounted on the heatsink 4. A coolant inlet tube 22 is connected to the coolant inlet 8 of the coolant tube 6 that is embedded into the heatsink 4. The coolant inlet tube 22 delivers liquid coolant to the coolant tube 6. The coolant outlet 10 of the coolant tube 6 is connected to a coolant outlet tube 24 which removes the coolant from the diode rectifier system 2.

The six diode modules 12 are mounted on the heatsink 4 and the heatsink 4 is kept at ground potential. For example, the diode clamp, or bracket, 16 is grounded to maintain the heatsink 4 at ground potential. As shown in FIG. 3, the diode rectifier system may also include fuses, coolant hoses, coolant valves, snubbers for electrical transient suppression, and buswork for carrying current to and from the rest of the diode rectifier system.

Maintaining the heatsink 4 at ground potential eliminates the ion driving process and reduces the rate of corrosion. Moreover, regular water may also be used instead of deionized water for further reductions in the corrosion rate. It should be appreciated, however, that deionized water may be used. For example, in the instance in which deionized water is the most conveniently available source of water that is temperature-regulated and monitored for adequate flow, the grounded nature of the heatsink and the use of, for example, stainless steel and PTFE, will minimize the impact of the corrosive nature of the deionized water.

The reliability of the diode rectifier system may also be improved by using stainless steel and PTFE for wetted surfaces, instead of copper and carbon steel, both of which erode much more quickly in deionized water. Improvements in reliability may also be achieved by using standard NPT and JIC 37° pipe fittings instead of O-rings and other custom fittings.

The diode rectifier system increases the reliability of the system by reducing the number of plumbing connections and by reducing the erosion-corrosion phenomena that contributed to leak formation in prior diode rectifier systems. The diode rectifier system 2 is also able to operate longer without erosion-corrosion, and/or the leaks of prior diode rectifier systems. The diode rectifier system 2 is also a less expensive diode rectifier system than current systems and requires a smaller number of hoses and heatsinks, thus reducing the expense of current liquid-cooled diode rectifier systems and air-cooled diode rectifier systems.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

1. A diode rectifier system for generator excitation, comprising:
a plurality of diode modules mounted on a heatsink; and
a coolant tube provided in the heatsink, wherein the heatsink is electrically grounded.

2. A diode rectifier system according to claim 1, wherein the coolant tube comprises a single pre-formed tube.

3. A diode rectifier system according to claim 2, wherein the single pre-formed tube comprises a stainless steel tube.

4. A diode rectifier system according to claim 3, wherein an inner surface of the stainless steel tube is coated with PTFE.

5. A diode rectifier system according to claim 1, wherein the coolant tube is embedded in the heatsink.

6. A diode rectifier system according to claim 1, wherein the heatsink comprises a machined aluminum block.

7. A diode rectifier system according to claim 1, wherein each diode module comprises a diode, a bracket, and an insulating layer between the diode and the heatsink.

8. A diode rectifier system according to claim 7, wherein the heatsink is electrically grounded through the bracket.

9. A diode rectifier system according to claim 7, wherein the insulating layer comprises alumina or aluminum nitride or a combination thereof.

10. A diode rectifier system according to claim 1, wherein the plurality of diode modules comprises at least six diode modules.

11. A method of cooling a diode rectifier system for generator excitation, the diode rectifier system comprising a plurality of diode modules mounted on a heatsink and a coolant tube provided in the heatsink, the method comprising:
providing a flow of liquid coolant in the coolant tube; and
electrically grounding the heatsink.

12. A method according to claim 11, wherein the liquid coolant comprises water.

13. A method according to claim 12, wherein the water comprises deionized water.

14. A method according to claim 11, wherein electrically grounding the heatsink comprises insulating diodes of the diode modules from the heatsink.

15. A method according to claim 14, wherein the diodes are insulated from the heatsink by alumina or aluminum nitride or a combination thereof.

16. A method according to claim 11, wherein the coolant tube comprises a single pre-formed tube.

17. A method according to claim 16, wherein the single pre-formed tube comprises a stainless steel tube.

18. A method according to claim 17, wherein an inner surface of the stainless steel tube is coated with PTFE.

19. A method according to claim 11, wherein the heatsink comprises a machined aluminum block.

20. A method according to claim 11, wherein the plurality of diode modules comprises at least six diode modules.
